(19) United States
(12) Patent Application Publication
(10) Pub. No.: US 2014/0075751 A1
(43) Pub. Date: Mar. 20, 2014

(54) METHOD FOR MANUFACTURING LED LEAD FRAME

(71) Applicant: I-CHIUN PRECISION INDUSTRY CO., LTD., New Taipei City (TW)

(72) Inventors: Ting-Hsi LI, New Taipei City (TW); Yu-Jen LIN, New Taipei City (TW)

(73) Assignee: I-CHIUN PRECISION INDUSTRY CO., LTD., New Taipei City (TW)

(21) Appl. No.: 13/732,728

(22) Filed: Jan. 2, 2013

(30) Foreign Application Priority Data
Sep. 19, 2012 (TW) 101134373

(51) Int. Cl. H05K 13/00

(52) U.S. Cl. CPC H05K 13/00
USPC 29/843

(57) ABSTRACT

The invention relates to a method for manufacturing LED lead frame. The method comprises steps of: (a) forming a metal base with a plurality of lead areas by injection molding; (b) electroplating the metal base; and (c) forming an insulating casing on each of the lead areas.

This application is based on and claims the benefit of Taiwan Application No. 101134373 filed Sep. 19, 2012 the entire disclosure of which is incorporated by reference herein.

### BACKGROUND OF THE INVENTION

1. Field of the Invention

The invention relates to a method for manufacturing LED lead frame, and in particular to a method for manufacturing LED lead frame having a step of forming a metal base with a plurality of lead areas by injection molding.

2. Related Art

Generally, light emitting diode is used for lighting apparatus such as display board of guiding lights. LED can efficiently and directly convert electrical energy to light, and has a service life up to ten thousands hours. In addition, LED is less fragile and power saving. However, every kind of LED requires a reasonable form of package. Package functions protection of LED chips, connecting external wires to electrodes mounted on LED chips and increases light emitting efficiency by a good design.

As the IC process technology pursues miniaturization, the technique of electric components connecting to the circuit board adopts surface mount device (SMD) type instead of plug-in type. SMD type LED has advantages of small size and is suitable for automatic production. SMD type LED is suitable for an electronic device such as a mobile phone, laptop or PDA screen backlight light source.

A conventional method of manufacturing SMD type LED comprises steps: stamping a metal base to form a metal base with a plurality of lead areas having pins; forming an insulating casing on each of the lead areas by injection molding and bending the pins; cutting each of the lead areas to obtain a plurality of lead frames; mounting chips in the insulating casing; electrically connecting the pins with the chips; and packaging the chips by applying epoxy resins to obtain a SMD type LED.

It's an inevitable trend to develop toward a high power LED. The problems of heat conduction and thermal dissipation coming from a high power LED become wanted to be solved by the industrial. However, a metal base is stamped to form a metal base with a plurality of lead areas having pins, the metal base having two metal portions with the same thickness which is not advantageous for a design of heat conduction and thermal dissipation, for example, a thermal dissipation block.

### SUMMARY OF THE INVENTION

It is a primary object of the present invention to provide a method for manufacturing LED lead frame having a step of forming a metal base with a plurality of lead areas by injection molding. The method may manufacture LED lead frame having two metal portions with different thickness.

In order to achieve the above-described object, the present invention provides a method for manufacturing LED lead frame comprising steps of: (a) forming a metal base with a plurality of lead areas by injection molding; (b) electroplating the metal base; and (c) forming an insulating casing on each of the lead areas. A first aspect of step (a) comprises steps of: (1) introducing a metallic material into an extruder barrel terminating at one end in a discharge nozzle; (2) moving the metallic material through the extruder barrel toward an accumulation chamber adjacent the discharge nozzle; (3) heating the metallic material to a temperature to convert the metallic material to a semi-solid slurry; (4) shearing and advancing the semi-solid slurry with a screw toward the accumulation chamber; and (5) applying to the semi-solid slurry accumulated in the accumulation chamber sufficient force to discharge the semi-solid slurry accumulated in the accumulation chamber through the discharge nozzle into a mold.

A second aspect of step (a) comprises steps of: (1) providing a liquidus liquid metal; (2) shearing and advancing the liquidus liquid metal with a screw toward an accumulation chamber while cooling the liquidus liquid metal to a temperature to convert the liquidus liquid metal to a semi-solid slurry; and (3) applying to the semi-solid slurry accumulated in the accumulation chamber sufficient force to discharge the semi-solid slurry accumulated in the accumulation chamber through a discharge nozzle adjacent the accumulation chamber into a mold. As described herein, “liquid metals” indicate amorphous metal alloys, but are not liquid at room temperature. Liquid metals behave more like glasses than metals so that someone calls them as metallic glasses.

Compared to prior art, the present invention provides a method for manufacturing LED lead frame having a step of forming a metal base with a plurality of lead areas by injection molding process. The method may manufacture LED lead frame having two metal portions with different thickness as required in design of heat conduction and thermal dissipation or environment of use. In addition, an injection molding process for forming metal base used in the present invention can avoid a drawback of a high residual stress from stamping metal sheet. Moreover, an injection molding process for forming metal base used in the present invention can form a metal base with a plurality of lead areas by a continuous process or a batch process as required.

### BRIEF DESCRIPTION OF THE DRAWINGS

FIG. 1 is a schematic flow chart showing an embodiment of a method for manufacturing LED lead frame according to the invention.

FIG. 2 is a schematic flow chart showing an embodiment of an injection molding process for forming metal base used in a method for manufacturing LED lead frame according to the invention.

FIG. 3 is a schematic flow chart showing another embodiment of an injection molding process for forming metal base used in a method for manufacturing LED lead frame according to the invention.

FIG. 4A is a schematic view showing elements formed in each step of FIG. 1.

FIG. 4B is a sectional schematic view showing a lead area in FIG. 4A.

FIG. 5 is a schematic view of injection molding apparatus used in FIG. 2.

FIG. 6 is a schematic view of injection molding apparatus used in FIG. 3.

### DETAILED DESCRIPTION OF THE INVENTION

The present invention will be apparent from the following detailed description, which proceeds with reference to the accompanying drawings. The accompanying drawings are not meant to be construed in a limiting sense, which are only for reference and explanation.

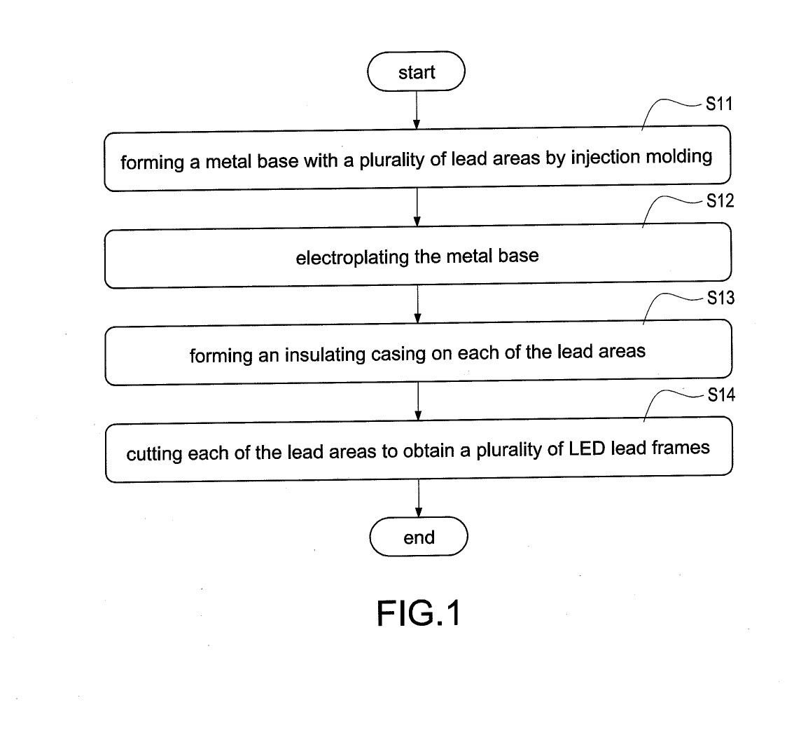

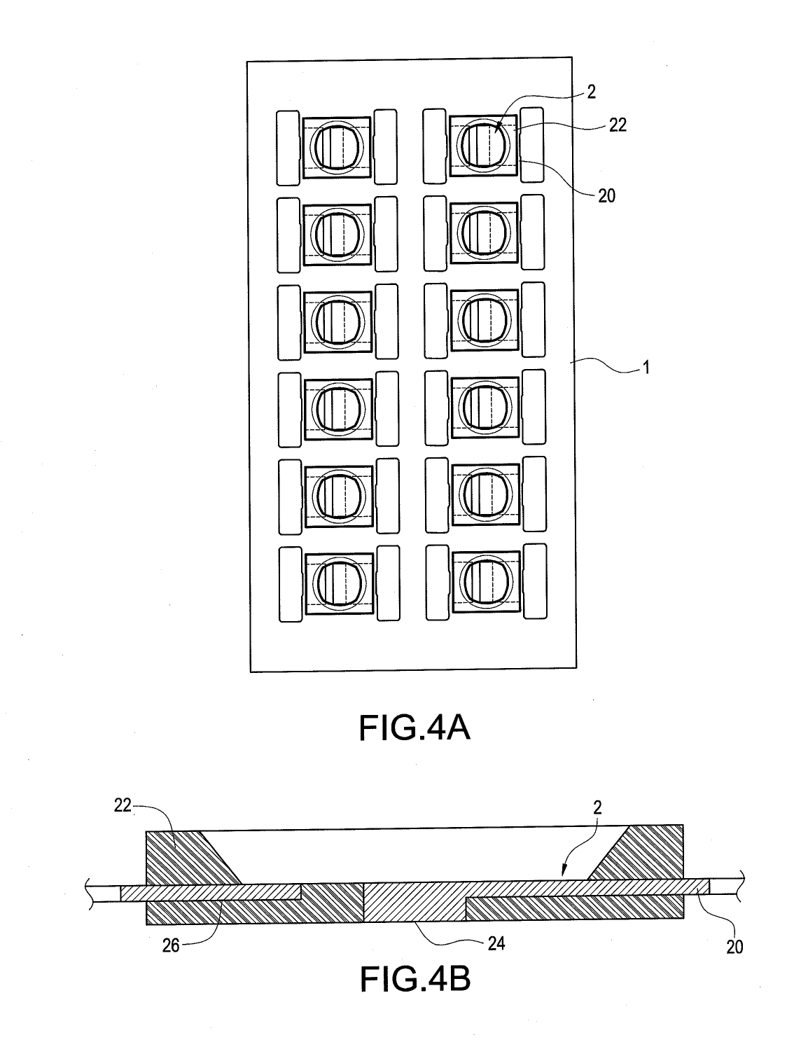

Please refer to FIGS. 1, 4A and 4B. FIG. 1 is a schematic flow chart showing an embodiment of a method for manufacturing LED lead frame according to the invention. FIG. 4A is a schematic view showing elements formed in each step of FIG. 1. FIG. 4B is a sectional schematic view showing a lead area in FIG. 4A. As shown in FIG. 1, the present embodiment of a method for manufacturing LED lead frame comprises steps S11-S14.

Firstly, in step S11, a metal base 1 with a plurality of lead areas 2 is formed by injection molding. Each of the lead areas 2 comprises at least one pin 20. In step S12, the metal base 1 is electroplated. Next, in step 13, an insulating casing 22 is formed on each of the lead areas 2 by injection molding, and the pins are bent. Finally, in step 14, each of the lead areas 2 is cut to obtain a plurality of LED lead frames. Please note that the step S11 of the embodiment discloses a metal base 1 with a plurality of lead areas 2 formed by injection molding which are only for reference and explanation. However, a metal base 1 with a lead area 2 can also be formed by injection molding, and the step S14 may be omitted in this case. The present embodiment provides a method for manufacturing LED lead frame having a step of forming a metal base with a plurality of lead areas by injection molding process. The method may manufacture LED lead frame having two metal portions 24, 26 with different thickness as required in design of heat conduction and thermal dissipation.

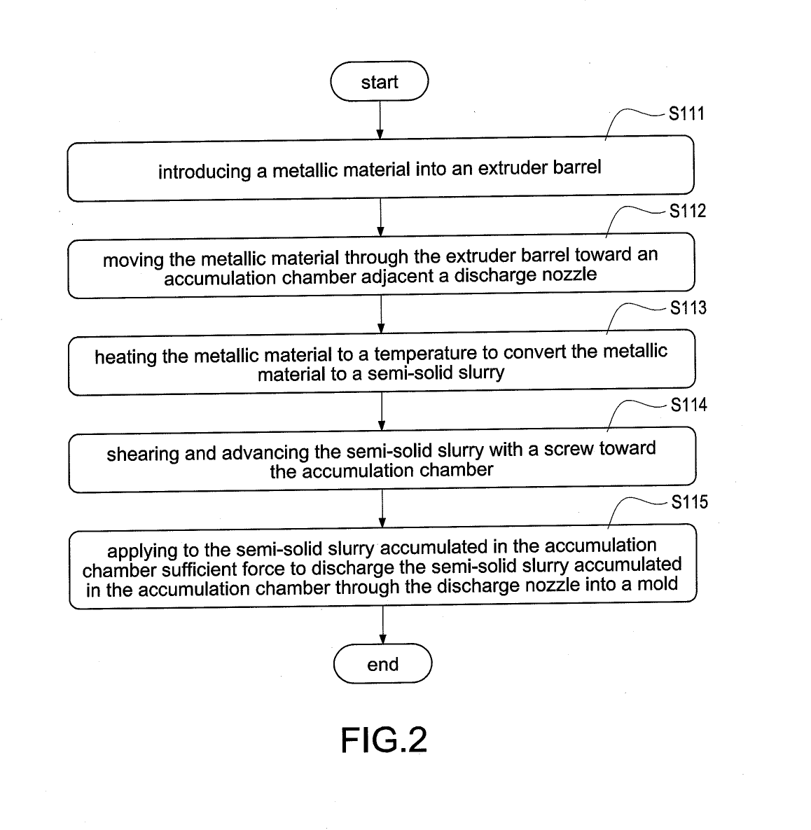

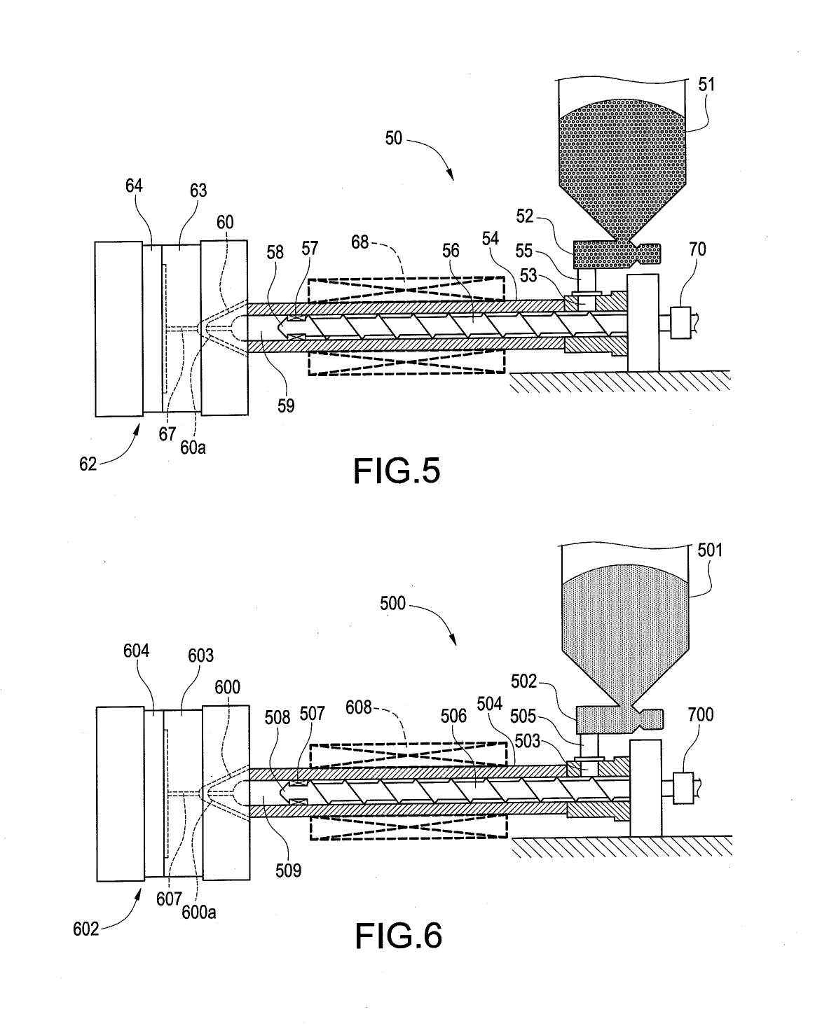

Next, please refer to FIGS. 2 and 5. FIG. 2 is a schematic flow chart showing an embodiment of an injection molding process for forming metal base used in a method for manufacturing LED lead frame according to the invention. FIG. 5 is a schematic view of injection molding apparatus used in FIG. 2. As shown in FIG. 2, the present embodiment of an injection molding process for forming metal base used in a method for manufacturing LED lead frame comprises steps S111-S115.

As shown in FIG. 5, an injection molding apparatus 50 comprises a feed hopper 51 for containing pellets of metallic material. A feeder 52 is connected to the bottom of the feed hopper 51. The feeder 52 comprises an auger (not shown) which functions to advance pellets of metallic material at a uniform rate to an extruder. The feeder 52 is connected to a feed throat 53 of an extruder barrel 54 through a vertical conduit 55. Also, inert gas is inputted and an atmosphere of inert gas is maintained in the conduit 55 and the extruder barrel 54 so as to prevent oxidation of pellets of metallic material which are fed in the conduit 55 and the extruder barrel 54.

The extruder barrel 54 has a rotatable extruder screw 56 inside for advancing metallic material. The extruder screw 56 has a check valve 57 and a screw tip 58 adjacent the discharge end of the extruder barrel 54. The discharge end of the extruder barrel 54 is provided with a nozzle 60 having a tip 60a for injection of semi-solid slurry. A suitable two-part mold 62 having a stationary half 63 fixed to a stationary platen and a movable half 64. As the stationary half 63 is connected with the movable half 64, they may define a cavity 67 aligned by the tip 60a of the nozzle 60 for injection of semi-solid slurry. The semi-solid slurry may be cured to form a metal base with a plurality of lead areas, each of lead areas having two metal portions with different thickness.

Operation of the injection molding apparatus 50 involves rotation of extruder screw 56 within the extruder barrel 54 to advance and continuously shear the metallic material supplied through the feed throat 53 to the accumulation chamber 59 between the screw tip 58 and the nozzle 60. Suitable temperature control device 68 may supply heat to the extruder barrel 54 to heat the metallic material. The heat may cause the pellets of metallic material to convert to semi-solid slurry at a temperature which is between its solid temperature and its liquid temperature. The semi-solid slurry is subjected to shearing action by the extruder screw 56 and the semi-solid slurry is continuously advanced toward the discharge end of the extruder barrel 54 to pass the check valve 57 in sufficient accumulated volume to permit high speed forward movement of the extruder screw 56 to complete a mold filling injection by a high speed injection apparatus 70.

Again, please refer to FIGS. 2 and 5. In step S111, pellets of metallic material with diameter about 3-5 mm are added into a feed hopper 51 and introduced into an extruder barrel 54 terminating at one end in a discharge nozzle 60 through the feeder 52, the conduit 55 and the feed throat 53 of the extruder barrel 54. The metallic material may be metal or alloy selected from the group consisting of copper, nickel, aluminum and magnesium. Alternatively, the metallic material may be metal or alloy selected from the group consisting of zirconium, nickel, copper, iron, titanium, palladium, platinum and gold.

In step S112, the metallic material may move toward an accumulation chamber adjacent the discharge nozzle through the extruder barrel. The metallic material contained in the extruder barrel 54 is advanced by the extruder screw 56.

In step S113, the metallic material is heated to a temperature of the semi-solid slurry. The temperature control device 68 is covered on the extruder barrel 54 outside. The temperature control device 68 comprises heating components and cooling components which is suitable used to heat the metallic material to a temperature between its solid temperature and its liquid temperature in conversion of pellets of metallic material to the semi-solid slurry. The temperature for heating the metallic material has to be maintained in a semi-solid state. However, the temperature has to be reduced to a proper temperature range by the cooling components as the temperature is higher than the liquidus temperature of the metallic material.

In step S114, the semi-solid slurry is sheared and advanced toward the accumulation chamber with a screw. In order to prevent dendritic crystalline growth, the semi-solid slurry is sheared with a screw. A predetermined temperature range is maintained to remain the semi-solid slurry state accumulated in the accumulation chamber and in conversion of pellets of metallic material to the semi-solid slurry.

In step S115, sufficient force is applied to the semi-solid slurry accumulated in the accumulation chamber to discharge the semi-solid slurry accumulated in the accumulation chamber through the discharge nozzle into a mold. The semi-solid slurry is subjected to shearing action by the extruder screw 56 and the semi-solid slurry is continuously advanced toward the discharge end of the extruder barrel 54 to pass the check valve 57 in sufficient accumulated volume to permit high speed forward movement of the extruder screw 56 to complete a mold filling injection by a high speed injection apparatus 70.

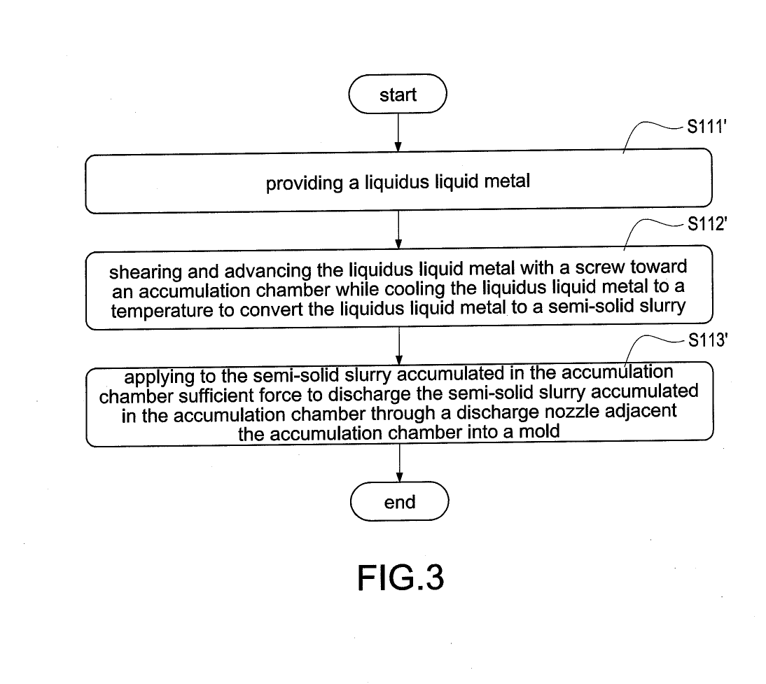

Next, please refer to FIGS. 3 and 6. FIG. 3 is a schematic flow chart showing another embodiment of an injection molding process for forming metal base used in a method for manufacturing LED lead frame according to the invention. FIG. 6 is a schematic view of injection molding apparatus used in FIG. 3. As shown in FIG. 3, the present embodiment of an injection molding process for forming metal base used in a method for manufacturing LED lead frame comprises steps S111′-S113′.

As shown in FIG. 6, an injection molding apparatus 500 comprises a feed hopper 501 for containing liquidus liquid metal. A feeder 502 is connected to the bottom of the feed hopper 501. The feeder 502 comprises a flow meter (not shown) which functions to advance liquidus liquid metal at a uniform rate to an extruder. The feeder 502 is connected to a feed throat 503 of an extruder barrel 504 through a vertical conduit 505. Also, inert gas is inputted and an atmosphere of inert gas is maintained in the conduit 505 and the extruder barrel 504 so as to prevent oxidation of liquidus liquid metal which is fed in the conduit 505 and the extruder barrel 504.

The extruder barrel 504 has a rotatable extruder screw 506 inside for advancing liquidus liquid metal. The extruder screw 506 has a check valve 507 and a screw tip 508 adjacent the discharge end of the extruder barrel 504. The discharge end of the extruder barrel 504 is provided with a nozzle 600 having a tip 600a for injection of semi-solid slurry. A suitable two-part mold 602 having a stationary half 603 fixed to a stationary platen and a movable half 604. As the stationary half 6003 is connected with the movable half 604, they may define a cavity 607 aligned by the tip 600a of the nozzle 600 for injection of semi-solid slurry. The semi-solid slurry may be cured to form a metal base with a plurality of lead areas, each of lead areas having two metal portions with different thickness.

Operation of the injection molding apparatus 500 involves rotation of extruder screw 506 within the extruder barrel 504 to advance and continuously shear the liquid metal supplied through the feed throat 503 to the accumulation chamber 509 between the screw tip 508 and the nozzle 600. Suitable temperature control device 608 may be used to cool the liquid metal in the extruder barrel 504. The cooling action may cause the liquidus liquid metal to convert to semi-solid slurry at a temperature which is between its solidus temperature and its liquidus temperature. The semi-solid slurry is subjected to shearing action by the extruder screw 506 and the semi-solid slurry is continuously advanced toward the discharge end of the extruder barrel 54 to pass the check valve 507 in sufficient accumulated volume to permit high speed forward movement of the extruder screw 506 to complete a mold filling injection by a high speed injection apparatus 700.

Again, please refer to FIGS. 3 and 6. In step S111′, a liquid metal is provided. The liquid metal may be metal or alloy selected from the group consisting of copper, nickel, aluminum and magnesium. Alternatively, the liquid metal may be metal or alloy selected from the group consisting of zirconium, nickel, copper, iron, titanium, palladium, platinum and gold.

In step S112′, the liquidus liquid metal is sheared and advanced with a screw toward an accumulation chamber while cooling the liquid metal to a temperature to convert the liquidus liquid metal to a semi-solid slurry. The liquid metal stored in a feed hopper 501 is introduced into an extruder barrel 504 terminating at one end in a discharge nozzle 600 through the feeder 502, the conduit 505 and the feed throat 503 of the extruder barrel 504. In order to prevent dendritic crystalline growth, the liquidus liquid metal is sheared with a screw 506 while cooling the liquidus liquid metal. A predetermined temperature range is maintained to remain the semi-solid slurry state accumulated in the accumulation chamber and in conversion of the liquidus liquid metal to the semi-solid slurry.

The temperature control device 608 is covered on the extruder barrel 504 outside. The temperature control device 608 comprises heating components and cooling components which is suitable used to cool the liquidus liquid metal to a temperature between its solidus temperature and its liquidus temperature in conversion of the liquidus liquid metal to the semi-solid slurry. The temperature for cooing the liquidus liquid metal has to be maintained in a semi-solid state. However, the temperature has to be raised to a proper temperature range by the heating components as the temperature is lower than the solidus temperature of the liquid metal.

In step S113′, sufficient force is applied to the semi-solid slurry accumulated in the accumulation chamber to discharge the semi-solid slurry accumulated in the accumulation chamber through the discharge nozzle into a mold. The semi-solid slurry is subjected to shearing action by the extruder screw 506 and the semi-solid slurry is continuously advanced toward the discharge end of the extruder barrel 504 to pass the check valve 507 in sufficient accumulated volume to permit high speed forward movement of the extruder screw 506 to complete a mold filling injection by a high speed injection apparatus 700.

While the invention is described in by way of examples and in terms of preferred embodiments, it is to be understood that the invention is not limited thereto. On the contrary, the aim is to cover all modifications, alternatives and equivalents falling within the spirit and scope of the invention as defined by the appended claims.

What is claimed is:

1. A method for manufacturing LED lead frame comprising steps of:
(a) forming a metal base with a plurality of lead areas by injection molding, wherein each of the lead areas has two metal portions with different thickness;
(b) electroplating the metal base; and
(c) forming an insulating casing on each of the lead areas.

2. The method for manufacturing LED lead frame according to claim 1, wherein the step (a) comprises the steps of:
(1) introducing a metallic material into an extruder barrel terminating at one end in a discharge nozzle;
(2) moving the metallic material through the extruder barrel toward an accumulation chamber adjacent the discharge nozzle;
(3) heating the metallic material to a temperature to convert the metallic material to a semi-solid slurry;
(4) shearing and advancing the semi-solid slurry with a screw toward the accumulation chamber; and
(5) applying to the semi-solid slurry accumulated in the accumulation chamber sufficient force to discharge the semi-solid slurry accumulated in the accumulation chamber through the discharge nozzle into a mold.

3. The method for manufacturing LED lead frame according to claim 2, further comprising maintaining a predetermined temperature range to remain the semi-solid slurry state accumulated in the accumulation chamber before the step (5), remaining the semi-solid slurry state accumulated in the accumulation chamber and the step (3) heating the metallic material to a temperature to convert the metallic material to a semi-solid slurry are completed by heating components and cooling components.

4. The method for manufacturing LED lead frame according to claim 2, wherein the metallic material is metal or alloy selected from the group consisting of copper, nickel, aluminum and magnesium.

5. The method for manufacturing LED lead frame according to claim 2, wherein the metallic material is metal or alloy selected from the group consisting of zirconium, nickel, copper, iron, titanium, palladium, platinum and gold.

6. The method for manufacturing LED lead frame according to claim 1, wherein the step (a) comprises the steps of:
(1) providing a liquidus liquid metal;
(2) shearing and advancing the liquidus liquid metal with a screw toward an accumulation chamber while cooling the liquidus liquid metal to a temperature to convert the liquidus liquid metal to a semi-solid slurry; and
(3) applying to the semi-solid slurry accumulated in the accumulation chamber sufficient force to discharge the semi-solid slurry accumulated in the accumulation chamber through a discharge nozzle adjacent the accumulation chamber into a mold.

7. The method for manufacturing LED lead frame according to claim 6, wherein the step (2) comprises introducing the liquidus liquid metal into an extruder barrel terminating at one end in a discharge nozzle, the extruder barrel having a screw inside, and the method for manufacturing LED lead frame further comprises maintaining a predetermined temperature range to remain the semi-solid slurry state accumulated in the accumulation chamber before the step (3), remaining the semi-solid slurry state accumulated in the accumulation chamber and the step (2) cooling the liquidus liquid metal to a temperature to convert the liquidus liquid metal to a semi-solid slurry are completed by heating components and cooling components.

8. The method for manufacturing LED lead frame according to claim 6, wherein the liquid metal is metal or alloy selected from the group consisting of copper, nickel, aluminum and magnesium.

9. The method for manufacturing LED lead frame according to claim 6, wherein the liquid metal is metal or alloy selected from the group consisting of zirconium, nickel, copper, iron, titanium, palladium, platinum and gold.

10. The method for manufacturing LED lead frame according to claim 1, wherein the step (a) comprises the steps of:
(1) heating the metallic material to a temperature to convert the metallic material to a semi-solid slurry;
(2) shearing the semi-solid slurry;
(3) advancing the semi-solid slurry toward an accumulation chamber; and
(4) discharging the semi-solid slurry accumulated in the accumulation chamber into a mold.
